(19) United States
(12) Patent Application Publication
(10) Pub. No.: US 2026/0101818 A1
(43) Pub. Date: Apr. 9, 2026

(54) SEMICONDUCTOR PACKAGE

(71) Applicant: Samsung Electronics Co., Ltd., Suwon-si (KR)

(72) Inventor: Younghun KIM, Suwon-si (KR)

(73) Assignee: Samsung Electronics Co., Ltd., Suwon-si (KR)

(21) Appl. No.: 19/089,243

(22) Filed: Mar. 25, 2025

(30) Foreign Application Priority Data
Sep. 6, 2024 (KR) 10-2024-0121492

(51) Int. Cl. H01L 23/00; H01L 23/538; H01L 25/07

(52) U.S. Cl. CPC H10W 90/00; H10W 70/60; H10W 70/611; H10W 72/884; H10W 90/20; H10W 90/724; H10W 90/732; H10W 90/754

(57) ABSTRACT

A semiconductor package includes a package substrate, a first semiconductor chip on the package substrate, a conductive connector between the package substrate and the first semiconductor chip, the conductive connector electrically connecting the package substrate to the first semiconductor chip, a second semiconductor chip contacting an upper surface of the first semiconductor chip, a vertical bonding wire between the package substrate and the second semiconductor chip, the vertical bonding wire extending in a vertical direction perpendicular to an upper surface of the package substrate, having an upper surface coplanar with the upper surface of the first semiconductor chip, and electrically connecting the package substrate to the second semiconductor chip, a bonding layer contacting an upper surface of the second semiconductor chip, and a third semiconductor chip contacting an upper surface of the bonding layer.

### CROSS-REFERENCE TO RELATED APPLICATION

This application claims priority under 35 U.S.C. § 119 to Korean Patent Application No. 10-2024-0121492, filed on Sep. 6, 2024 in the Korean Intellectual Property Office (KIPO), the contents of which are herein incorporated by reference in their entirety.

### BACKGROUND

### 1. Field

Some example embodiments relate to a semiconductor package. For example, some example embodiments relate to a semiconductor package including a plurality of semiconductor chips stacked on a substrate.

### 2. Description of the Related Art

In a multi-chip package including a plurality of semiconductor chips stacked on a package substrate, a plurality of semiconductor chips may be further stacked on the semiconductor chip using a bonding layer, and each of the semiconductor chips may be electrically connected to the package substrate through bonding wires.

However, a vertical thickness of the multi-chip package may increase due to the bonding wires.

### SUMMARY

Some example embodiments provide a semiconductor package having enhanced electrical characteristics.

According to some example embodiments, there is provided a semiconductor package. The semiconductor package may include a package substrate, a first semiconductor chip on the package substrate, a conductive connector between the package substrate and the first semiconductor chip, the conductive connector electrically connecting the package substrate to the first semiconductor chip, a second semiconductor chip contacting an upper surface of the first semiconductor chip, a vertical bonding wire between the package substrate and the second semiconductor chip, the vertical bonding wire extending in a vertical direction perpendicular to an upper surface of the package substrate, having an upper surface that is coplanar with the upper surface of the first semiconductor chip, and electrically connecting the package substrate to the second semiconductor chip, a bonding layer contacting an upper surface of the second semiconductor chip, and a third semiconductor chip contacting an upper surface of the bonding layer.

According to some example embodiments, there is provided a semiconductor package. The semiconductor package may include a package substrate, a first semiconductor chip on the package substrate, a conductive connector between the package substrate and the first semiconductor chip, the conductive connector electrically connecting the package substrate to the first semiconductor chip, a second semiconductor chip over the first semiconductor chip, the second semiconductor chip being spaced apart from the first semiconductor chip in a vertical direction perpendicular to an upper surface of the substrate, a vertical bonding wire extending in the vertical direction between the package substrate and the second semiconductor chip, a bonding layer contacting an upper surface of the second semiconductor chip, and a third semiconductor chip contacting an upper surface of the bonding layer. A distance between the first semiconductor chip and the second semiconductor chips in the vertical direction may be less than a thickness of the bonding layer in the vertical direction.

According to some example embodiments, there is provided a semiconductor package. The semiconductor package may include a package substrate, a first semiconductor chip on the package substrate, a conductive connector between the package substrate and the first semiconductor chip, the conductive connector electrically connecting the package substrate to the first semiconductor chip, a second semiconductor chip contacting an upper surface of the first semiconductor chip, a vertical bonding wire between the package substrate and the second semiconductor chip, the vertical bonding wire extending in a vertical direction perpendicular to an upper surface of the package substrate, having an upper surface coplanar with the upper surface of the first semiconductor chip, and electrically connecting the package substrate to the second semiconductor chip, a first bonding layer contacting an upper surface of the second semiconductor chip, a third semiconductor chip contacting an upper surface of the first bonding layer, a first bonding wire electrically connecting the third semiconductor chip to the package substrate, a second bonding layer contacting an upper surface of the third semiconductor chip, a fourth semiconductor chip contacting an upper surface of the second bonding layer, and a second bonding wire electrically connecting the fourth semiconductor chip to the package substrate.

The semiconductor package in accordance with some example embodiments may have a reduced vertical thickness.

### BRIEF DESCRIPTION OF THE DRAWINGS

FIG. 1 is a plan view illustrating a semiconductor package in accordance with some example embodiments, and FIG. 2 is a cross-sectional view taken along line A-A′ of FIG. 1.

FIGS. 3 to 7 are cross-sectional views illustrating a method of manufacturing a semiconductor package in accordance with some example embodiments.

FIG. 8 is a cross-sectional view illustrating a semiconductor package in accordance with some example embodiments.

FIG. 9 is a plan view illustrating a semiconductor package in accordance with some example embodiments, and FIG. 10 is a cross-sectional view taken along line A-A′ of FIG. 9.

### DETAILED DESCRIPTION

Hereinafter, some example embodiments will be explained in detail with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, two directions among horizontal directions that are substantially parallel to an upper surface of a substrate or a chip may be referred to as first and second directions D1 and D2, respectively, and a vertical direction that is substantially perpendicular to the upper surface of the substrate or the chip may be referred to as a third direction D3. In some example embodiments, the first and second directions D1 and D2 may be substantially perpendicular to each other.

When an element is referred to as being “connected to” or “electrically connected to” another element, the element may be directly connected to the other element, or one or more other intervening elements may be present. For example, an element described as being “connected to” another element may be “electrically connected to” the other element. In contrast, when an element is referred to as being “directly connected to” another element there are no intervening elements present.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%. Further, regardless of whether numerical values or shapes are modified as “about” or “substantially,” it will be understood that these values and shapes should be construed as including a manufacturing or operational tolerance (e.g., ±10%) around the stated numerical values or shapes.

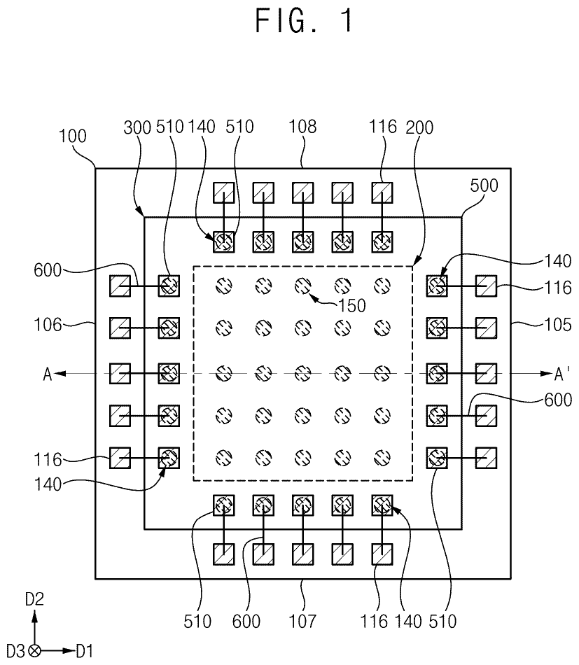

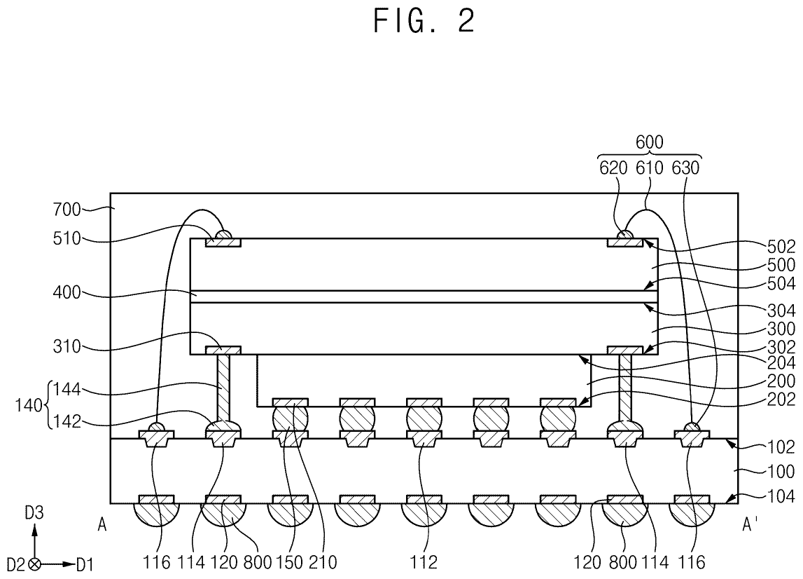

FIG. 1 is a plan view illustrating a semiconductor package in accordance with some example embodiments, and FIG. 2 is a cross-sectional view taken along line A-A′ of FIG. 1.

Referring to FIGS. 1 and 2, the semiconductor package may include a package substrate 100, first to third semiconductor chips 200, 300, and 500, first and second conductive connection members 150 and 800, a vertical bonding wire 140, a first bonding layer 400, a first bonding wire 600, and/or a molding member 700. The conductive connection members 150 and 800 may be referred to as conductive connectors 150 and 800.

The package substrate 100 may include first and second surfaces 102 and 104 opposite to each other in the third direction D3. The package substrate 100 may further include first and second side surfaces 105 and 106 opposite to each other in the first direction D1, and third and fourth side surfaces 107 and 108 opposite to each other in the second direction D2.

The package substrate 100 may be a printed circuit board (PCB). The PCB may be a multi-layered circuit board including various circuit patterns. In some example embodiments, the package substrate 100 may include, e.g., first to third substrate pads 112, 114, and 116 adjacent to the first surface 102 of the package substrate 100, and a fourth substrate pad 120 adjacent to the second surface 104 of the package substrate 100.

In some example embodiments, in a plan view, the first substrate pad 112 may be disposed at a central portion of the package substrate 110, the third substrate pad 116 may be disposed at an edge portion of the package substrate 100, and the second substrate pad 114 may be disposed between the first and third substrate pads 112 and 116.

In some example embodiments, in a plan view, a plurality of first substrate pads 112, a plurality of second substrate pads 114, and/or and a plurality of third substrate pads 116 may be spaced apart from each, or one or more, other in each of the first and/or second directions D1 and/or D2, the second substrate pads 114 may surround the first substrate pads 112, and/or the third substrate pads 116 may surround the second substrate pads 114.

In some example embodiments, the third substrate pads 116 may be disposed at first to fourth edge portions of the package substrate 100, which may be adjacent to the first to fourth side surfaces, respectively, of the package substrate 100. A plurality of third substrate pads 116 may be spaced apart from each other in the second direction D2 at each, or one or more, of the first and/or second edge portions of the package substrate 100, and/or a plurality of third substrate pads 116 may be spaced apart from each other in the first direction D1 at each, or one or more, of the third and/or fourth edge portions of the package substrate 100.

The second substrate pads 114, which are disposed at each, or one or more, of the first and/or second edge portions of the package substrate 100, may be disposed between the first and third substrate pads 112 and 116 corresponding to each other in the first direction D1, and the second substrate pads 114, which are disposed at each, or one or more, of the third and/or fourth edge portions of the package substrate 100, may be disposed between the first and third substrate pads 112 and 116 corresponding to each other in the second direction D2.

Each, or one or more, of the first to fourth substrate pads 112, 14, 116 and/or 120 may include a metal such as nickel, copper, aluminum, gold, tungsten, etc., a metal nitride, a metal silicide, etc.

The first semiconductor chip 200 may include first and second surfaces 202 and 204 opposite to each other in the third direction D3, and an active layer may be disposed at a portion of the first semiconductor chip 200 adjacent to the first surface 202. Thus, the first surface 202 of the first semiconductor chip 200 may be an active surface, and the second surface 204 of the first semiconductor chip 200 may be an inactive surface.

A circuit device, for example, a logic device, a DRAM device, a flash memory device, etc., may be disposed at the active layer, and the circuit device may include a plurality of circuit patterns and/or wiring structures. The first semiconductor chip 200 may include, e.g., a first chip pad 210 adjacent to the first surface 202 of the first semiconductor chip 200, which may be a part of the wiring structures.

In some example embodiments, a plurality of first chip pads 210 may be spaced apart from each other in each, or one or more, of the first and/or second directions D1 and/or D2, and may overlap the first substrate pads 112, respectively, of the package substrate 100 in the third direction D3.

The first conductive connection member 150 may contact an upper surface of the first substrate pad 112 of the package substrate 100 and a lower surface of the first chip pad 210, and may electrically connect the first substrate pad 112 to the first chip pad 210.

The first conductive connection member 150 may be a conductive bump and/or a conductive ball including, e.g., solder.

The second semiconductor chip 300 may include first and second surfaces 302 and 304 opposite to each other in the third direction D3, and an active layer may be disposed at a portion of the second semiconductor chip 300 adjacent to the first surface 302. Thus, the first surface 302 of the second semiconductor chip 300 may be an active surface, and the second surface 304 of the second semiconductor chip 300 may be an inactive surface.

A circuit device, for example, a logic device, a DRAM device, a flash memory device, etc., may be disposed at the active layer, and the circuit device may include a plurality of circuit patterns and/or wiring structures.

The second semiconductor chip 300 may include, e.g., a second chip pad 310 adjacent to the first surface 302 of the second semiconductor chip 300, which may be a part of the wiring structures. In some example embodiments, a plurality of second chip pads 310 may be spaced apart from each other in each, or one or more, of the first and/or second directions D1 and/or D2, and may overlap the second substrate pads 114, respectively, of the package substrate 100 in the third direction D3. Thus, the second chip pads 310 may be disposed at edge portions of the second semiconductor chip 300, which may be disposed in, e.g., a rectangular ring shape in a plan view.

In some example embodiments, the first surface 302 of the second semiconductor chip 300 may contact the second surface 204 of the first semiconductor chip 200. However, the second surface 204 of the first semiconductor chip 200 is the inactive surface, and thus the first and second semiconductor chips 200 and 300 may be electrically insulated from each other. In some example embodiments, a planar area of the second semiconductor chip 300 may be greater than a planar area of the first semiconductor chip 200, and the second chip pads 310 may not overlap the first semiconductor chip 200 in the third direction D3.

The vertical bonding wire 140 may be disposed between the second substrate pad 114 of the package substrate 100 and the second chip pad 310 of the second semiconductor chip 300. In some example embodiments, a plurality of vertical bonding wires 140 may be spaced apart from each other in each of the first and second directions D1 and D2, which may correspond to the second substrate pads 114 and the second chip pads 310. In some example embodiments, the vertical bonding wires 140 may be disposed in a rectangular ring shape in a plan view.

In some example embodiments, the vertical bonding wire 140 may include a first adhesion portion 142, which may contact an upper surface of the second substrate pad 114 and have, e.g., a semi-spherical shape, and/or a vertical extension portion 144, which may be disposed on the first adhesion portion 142, have a pillar shape extending in the third direction D3 and/or contact a lower surface of the second chip pad 310. An upper surface of the vertical extension portion 144 of the vertical bonding wire 140 may be bonded with the lower surface of the second chip pad 310, so that the second semiconductor chip 300 may be bonded with the vertical bonding wire 140.

In some example embodiments, an upper surface of the vertical bonding wire 140 may be substantially coplanar with the second surface 204 of the first semiconductor chip 200.

The vertical bonding wire 140 may include a metal such as gold, silver, chrome, nickel, molybdenum, tungsten, titanium, tin, etc. In some example embodiments, the vertical bonding wire may include gold.

The first bonding layer 400 may be disposed on and bonded with the second surface 304 of the second semiconductor chip 300. The first bonding layer 400 may include, e.g., die attach film (DAF), non-conductive film (NCF), etc.

The third semiconductor chip 500 may be bonded with an upper surface of the first bonding layer 400.

The third semiconductor chip 500 may include first and second surfaces 502 and 504 opposite to each other in the third direction D3, and an active layer may be disposed at a portion of the third semiconductor chip 500 adjacent to the first surface 502. Thus, the first surface 502 of the third semiconductor chip 500 may be an active surface, and the second surface 504 of the third semiconductor chip 500 may be an inactive surface.

A circuit device, for example, a logic device, a DRAM device, a flash memory device, etc., may be disposed at the active layer, and the circuit device may include a plurality of circuit patterns and/or wiring structures.

The third semiconductor chip 500 may include, e.g., a third chip pad 510 adjacent to the first surface 502 of the third semiconductor chip 500, which may be a part of the wiring structures. In some example embodiments, a plurality of third chip pads 510 may be spaced apart from each other in each, or one or more, of the first and/or second directions D1 and/or D2, and the third chip pads 510 may be disposed at edge portions of the third semiconductor chip 500. In some example embodiments, the third chip pads 510 may be disposed in, e.g., a rectangular ring shape in a plan view.

Each, or one or more, of the first to third chip pads 210, 310 and/or 510 may include a metal such as nickel, copper, aluminum, gold, tungsten, etc., a metal nitride, a metal silicide, etc.

In some example embodiments, sidewalls of the second and/or third semiconductor chips 300 and/or 500 and the first bonding layer 400 may be aligned with each other in the third direction D3, and the second and/or third semiconductor chips 300 and/or 500 and the first bonding layer 400 may have substantially the same planar area.

The first bonding wire 600 may include a second adhesion portion 620, which may contact an upper surface of the third chip pad 510 of the third semiconductor chip 500 and have, e.g., a semi-spherical shape, a third adhesion portion 630, which may contact an upper surface of the third substrate pad 116 of the package substrate 100 and have, e.g., a semi-spherical shape, and/or a first extension portion 610, which may be disposed between the second and third adhesion portions 620 and 630, extend in the third direction D3 and be partially bent. In some example embodiments, a plurality of first bonding wires 600 may be spaced apart from each other in each, or one or more, of the first and/or second directions D1 and/or D2, which may correspond to the third chip pads 510 and/or the third substrate pads 116. In some example embodiments, the first bonding wires 600 may be disposed in a rectangular ring shape in a plan view.

The first bonding wire 600 may include a metal such as gold, silver, chromium, nickel, molybdenum, tungsten, titanium, tin, etc.

The molding member 700 may be disposed on the package substrate 100, and may cover the first conductive connection member 150, the vertical bonding wire 140, the first to third semiconductor chips 200, 300 and/or 500, the first bonding layer 400, and/or the first bonding wire 600. The molding member 700 may include, e.g., epoxy molding compound (EMC).

The second conductive connection member 800 may contact a lower surface of the fourth substrate pad 120 of the package substrate 100. In some example embodiments, a plurality of second conductive connection members 800 may be spaced apart from each other in each, or one or more, of the first and/or second directions D1 and/or D2. The second conductive connection member 800 may be a conductive bump and/or a conductive ball including, e.g., solder.

In the semiconductor package in accordance with some example embodiments, the third semiconductor chip 500 bonded to the second semiconductor chip 300 through the first bonding layer 400 may include the third chip pad 510 adjacent to the first surface 502, that is, an upper surface of the third semiconductor chip 500, and the third chip pad 510 may be electrically connected to the third substrate pad 116 of the package substrate 100 through the first bonding wire 600.

The second semiconductor chip 300 contacting the second surface 204, that is, an upper surface of the first semiconductor chip 200, may include the second chip pad 310 adjacent to the first surface 302, that is, a lower surface of the second semiconductor chip 300, and the second chip pad 310 may be electrically connected to the second substrate pad 114 of the package substrate 100 through the vertical bonding wire 140.

Thus, when compared to a semiconductor package in which the second semiconductor chip 300 is bonded to the upper surface of the first semiconductor chip 200 through a bonding layer, the semiconductor package may have a reduced thickness in the third direction D3.

If a chip pad is disposed on the upper surface of the second semiconductor chip 300 and the chip pad is electrically connected to the package substrate 100 through a bonding wire, a planar area of the third semiconductor chip 500 disposed on the second semiconductor chip 300 may be less than a planar area of the second semiconductor chip 300 by an area of the bonding wire.

However, in some example embodiments, the second semiconductor chip 300 may be electrically connected to the package substrate 100 through the second chip pad 310 adjacent to the first surface 302, that is, the lower surface of the second semiconductor chip 300 and the vertical bonding wire 140 contacting the lower surface of the second chip pad 310, and thus the planar area of the third semiconductor chip 500 may be substantially the same as that of the second semiconductor chip 300, and the sidewall of the third semiconductor chip 500 may be aligned with the sidewall of the second semiconductor chip 300 in the third direction D3.

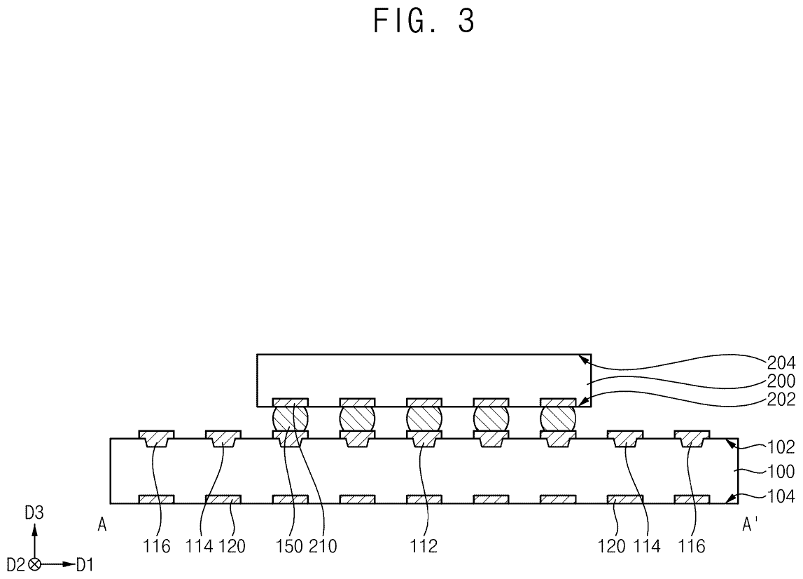

FIGS. 3 to 7 are cross-sectional views illustrating a method of manufacturing a semiconductor package in accordance with some example embodiments.

Referring to FIG. 3, a first semiconductor chip 200 may be connected to a first surface 102 of a package substrate 100 through a first conductive connection member 150.

The package substrate 100 may include first and second surfaces 102 and 104 opposite to each other in the third direction D3, and may be a printed circuit board (PCB). The package substrate 100 may include, e.g., first to third substrate pads 112, 114, and 116 adjacent to the first surface 102 of the package substrate 100, and/or a fourth substrate pad 120 adjacent to the second surface 104 of the package substrate 100.

The first semiconductor chip 200 may include first and second surfaces 202 and 204 opposite to each other in the third direction D3, and an active layer may be disposed at a portion of the first semiconductor chip 200 adjacent to the first surface 202. The first semiconductor chip 200 may include, e.g., a first chip pad 210 adjacent to the first surface 202 of the first semiconductor chip 200, which may be a part of the wiring structures.

The first conductive connection member 150 may contact an upper surface of the first substrate pad 112 of the package substrate 100 and/or a lower surface of the first chip pad 210.

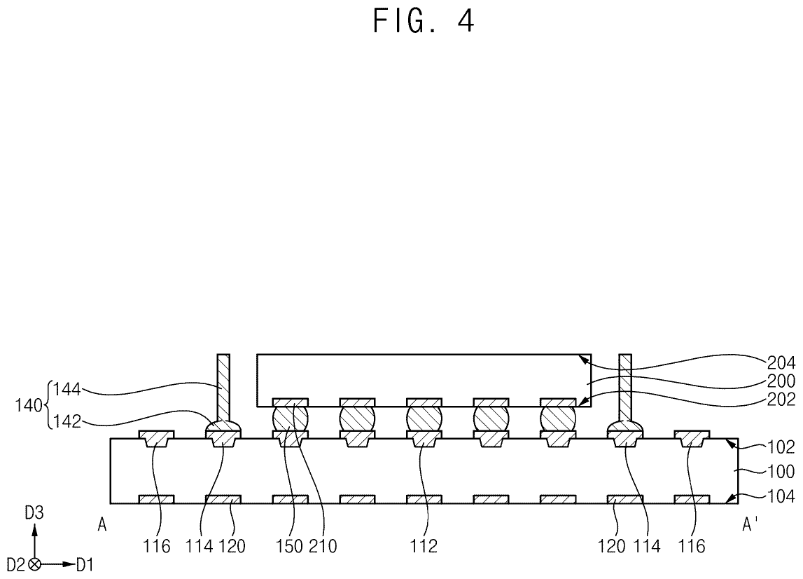

Referring to FIG. 4, a wire bonding process may be performed using a capillary to form a vertical bonding wire 140 on the second substrate pad 114 of the package substrate 100.

In some example embodiments, the vertical bonding wire 140 may include a first adhesion portion 142, which may contact an upper surface of the second substrate pad 114 and have, e.g., a semi-spherical shape, and a vertical extension portion 144, which may be disposed on the first adhesion portion 142 and have a pillar shape extending in the third direction D3.

In some example embodiments, an upper surface of the vertical bonding wire 140 may be substantially coplanar with the second surface 204 of the first semiconductor chip 200.

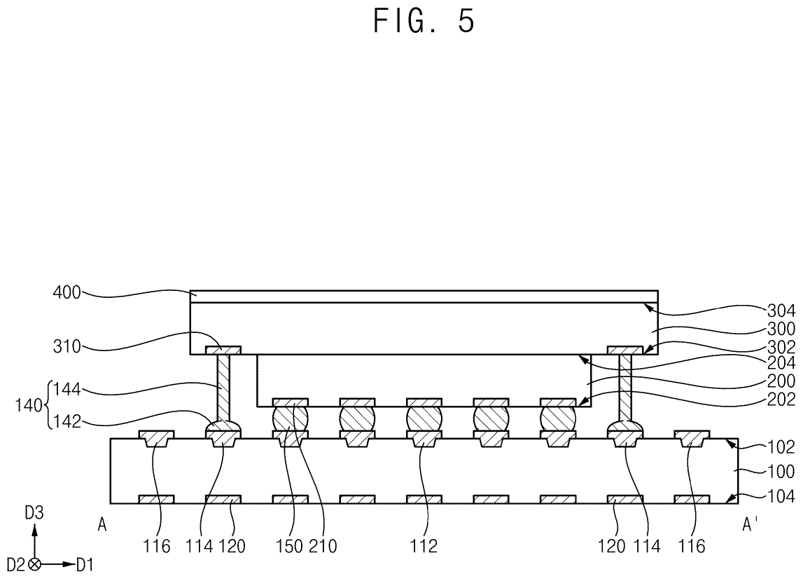

Referring to FIG. 5, a second semiconductor chip 300 may be stacked on the vertical bonding wire 140 and/or the first semiconductor chip 200.

The second semiconductor chip 300 may include first and second surfaces 302 and 304 opposite to each other in the third direction D3, and an active layer may be disposed at a portion of the second semiconductor chip 300 adjacent to the first surface 302. The second semiconductor chip 300 may include, e.g., a second chip pad 310 adjacent to the first surface 302 of the second semiconductor chip 300, which may be a part of the wiring structures. The second chip pad 310 may contact an upper surface of the vertical bonding wire 140.

In some example embodiments, the first surface 302 of the second semiconductor chip 300 may contact the second surface 204 of the first semiconductor chip 200. However, the second surface 204 of the first semiconductor chip 200 is the inactive surface, and thus the first and second semiconductor chips 200 and 300 may be electrically insulated from each other.

A first bonding layer 400 may be attached to the second surface 304 of the second semiconductor chip 300.

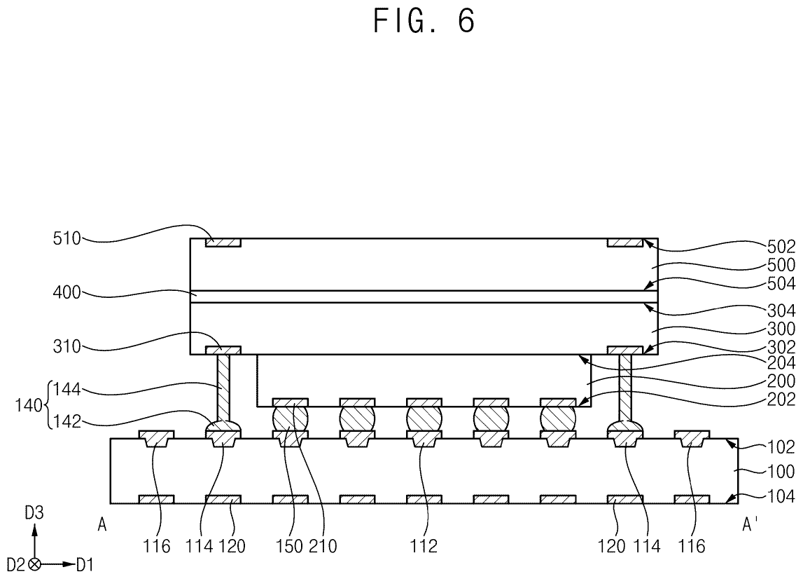

Referring to FIG. 6, a third semiconductor chip 500 may be bonded to the first bonding layer 400.

The third semiconductor chip 500 may include first and second surfaces 502 and 504 opposite to each other in the third direction D3, and an active layer may be disposed at a portion of the third semiconductor chip 500 adjacent to the first surface 502. The third semiconductor chip 500 may include, e.g., a third chip pad 510 adjacent to the first surface 502 of the third semiconductor chip 500, which may be a part of the wiring structures.

In some example embodiments, the second surface 504 of the third semiconductor chip 500 may contact an upper surface of the first bonding layer 400.

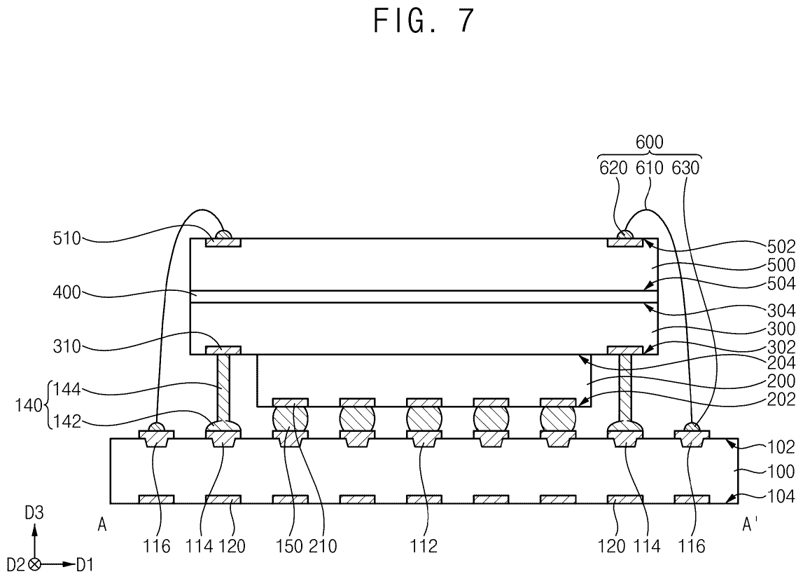

Referring to FIG. 7, a wire bonding process may be performed using a capillary to form a first bonding wire 600 that may contact the third chip pad 510 and the third substrate pad 116 to electrically connect the third chip pad 510 and the third substrate pad 116 to each other.

In some example embodiments, the first bonding wire 600 may include a second adhesion portion 620, which may contact an upper surface of the third chip pad 510 of the third semiconductor chip 500 and have, e.g., a semi-spherical shape, a third adhesion portion 630, which may contact an upper surface of the third substrate pad 116 of the package substrate 100 and have, e.g., a semi-spherical shape, and/or a first extension portion 610, which may be disposed between the second and third adhesion portions 620 and 630, extend in the third direction D3, and be partially bent.

Referring to back to FIGS. 1 and 2, a molding member 700 may be formed on the package substrate 100 to cover the first conductive connection member 150, the vertical bonding wire 140, the first to third semiconductor chips 200, 300, and 500, the first bonding layer 400, and/or the first bonding wire 600. A second conductive connection member 800 may be formed to contact the fourth substrate pad 120 of the package substrate 100, so that the manufacturing of the semiconductor package may be completed.

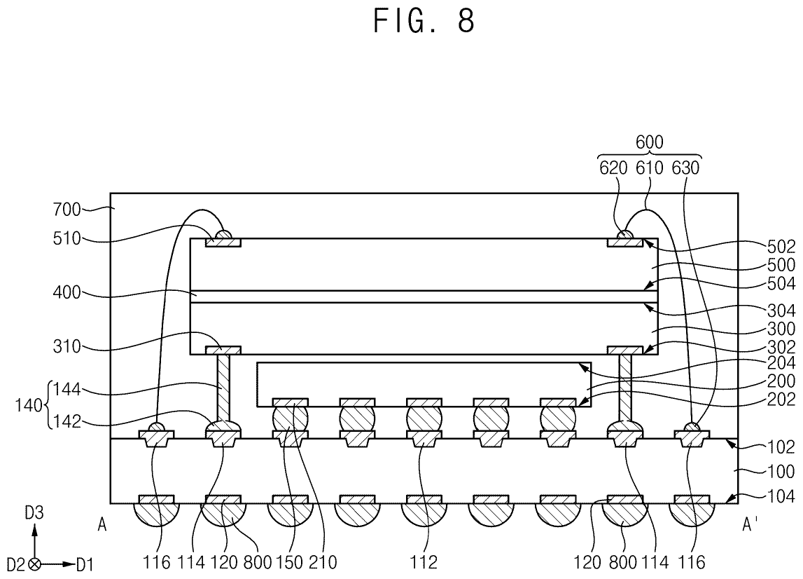

FIG. 8 is a cross-sectional view illustrating a semiconductor package in accordance with some example embodiments, which may correspond to FIG. 2.

This semiconductor package may be substantially the same as or similar to that of FIGS. 1 and 2, except for the relative positions of the first and second semiconductor chips and the vertical bonding wire. Thus, repeated explanations are omitted herein.

Referring to FIG. 8, the upper surface of the vertical bonding wire 140 may be higher than the upper surface, that is, the second surface of the first semiconductor chip 200.

Thus, the second surface 204 of the first semiconductor chip 200 may be lower than the lower surface, that is, the first surface 302 of the second semiconductor chip 300, and the first and second semiconductor chips 200 and 300 may not contact each other but may be spaced apart from each other.

In some example embodiments, a distance between the first and second semiconductor chips 200 and 300 in the third direction D3 may be less than a thickness in the third direction D3 of the first bonding layer 400, and thus the semiconductor package may still have a reduced thickness.

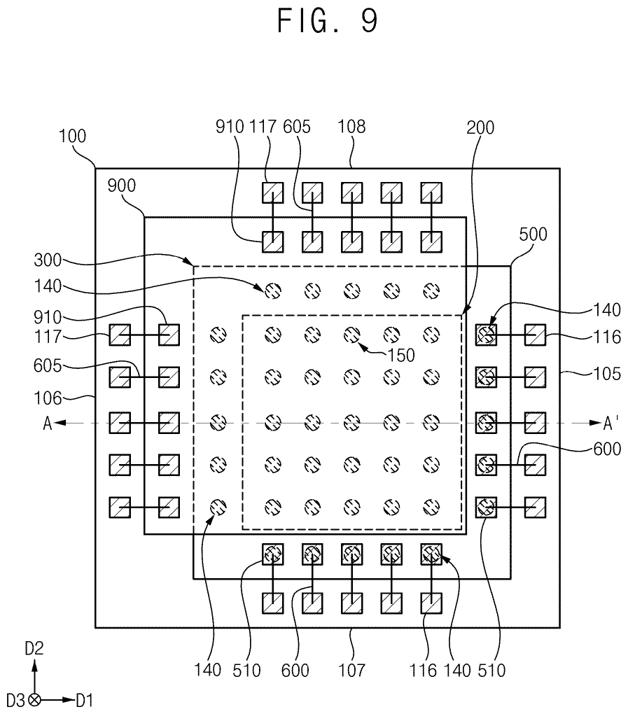

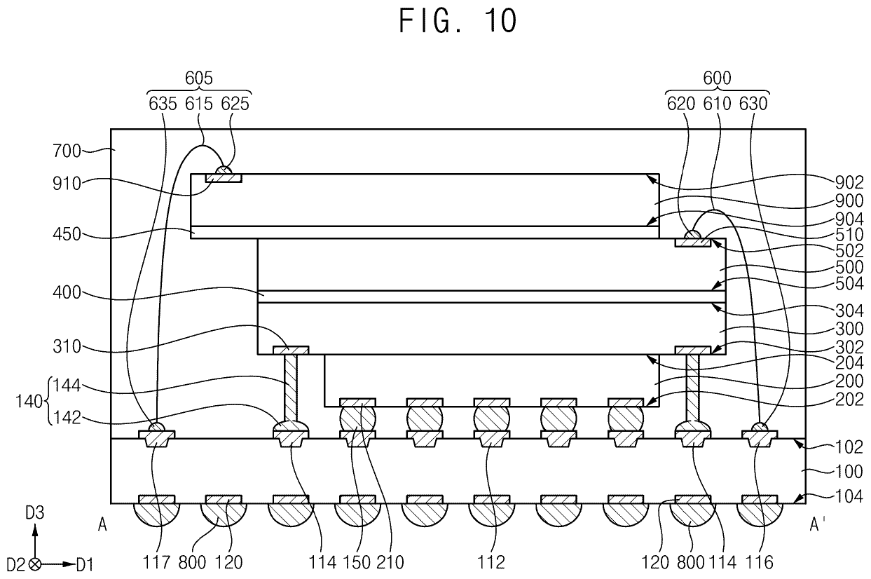

FIG. 9 is a plan view illustrating a semiconductor package in accordance with some example embodiments, and FIG. 10 is a cross-sectional view taken along line A-A′ of FIG. 9.

FIG. 9 does not show the molding member in order to avoid the complexity of the drawing.

The example semiconductor package shown in FIGS. 9 and 10 may be substantially the same as or similar to that of FIGS. 1 and 2, except for some elements, and thus repeated explanations are omitted herein.

Referring to FIGS. 9 and 10, the semiconductor package may further include a fourth semiconductor chip 900, a second bonding layer 450 and/or a second bonding wire 605.

Unlike those of FIGS. 1 and 2, the third substrate pads 116 of the package substrate 100 may be disposed at neighboring two edge portions of the package substrate 100.

That is, the third substrate pads 116 may be disposed at the first and/or third edge portions of the package substrate 100 adjacent to the first and/or third side surfaces 105 and/or 107, respectively, of the package substrate 100. A plurality of third substrate pads 116 may be spaced apart from each other in the second direction D2 at the first edge portion of the package substrate 100, and/or a plurality of third substrate pads 116 may be spaced apart from each other in the first direction D1 at the third edge portion of the package substrate 100.

Distances from the third substrate pads 116 disposed at the first edge portion of the package substrate 100 to the first side surface 105 of the package substrate 100 in the first direction D1 may be less than distances from corresponding ones of the second substrate pads 114 to the first side surface 105 of the package substrate 100 in the first direction D1, and distances from the third substrate pads 116 disposed at the third edge portion of the package substrate 100 to the third side surface 107 of the package substrate 100 in the second direction D2 may be less than distances from corresponding ones of the second substrate pads 114 to the third side surface 107 of the package substrate 100 in the second direction D2.

The package substrate 100 may further include fifth substrate pads 117 disposed at at least one of neighboring two edge portions, that is, the second and/or fourth edge portions of the package substrate 100 adjacent to the second and/or fourth side surfaces 106 and 108, respectively, of the package substrate 100.

In some example embodiments, a plurality of fifth substrate pads 117 may be spaced apart from each other in the second direction D2 at the second edge portion of the package substrate 100, and/or a plurality of fifth substrate pads 117 may be spaced apart from each other in the first direction D1 at the fourth edge portion of the package substrate 100.

Distances from the fifth substrate pads 117 disposed at the second edge portion of the package substrate 100 to the second side surface 106 of the package substrate 100 in the first direction D1 may be less than distances from corresponding ones of the second substrate pads 114 to the second side surface 106 of the package substrate 100 in the first direction D1, and distances from the fifth substrate pads 117 disposed at the fourth edge portion of the package substrate 100 to the fourth side surface 108 of the package substrate 100 in the second direction D2 may be less than distances from corresponding ones of the second substrate pads 114 to the fourth side surface 108 of the package substrate 100 in the second direction D2.

The third chip pads 510 of the third semiconductor chip 500 may be disposed at neighboring two edge portions of the third semiconductor chip 500.

In some example embodiments, the fourth semiconductor chip 900 may include first and second surfaces 902 and 904 opposite to each other in the third direction D3, and an active layer may be disposed at a portion of the fourth semiconductor chip 900 adjacent to the first surface 902. Thus, the first surface 902 of the fourth semiconductor chip 900 may be an active surface, and the second surface 904 of the fourth semiconductor chip 900 may be an inactive surface.

A circuit device, for example, a logic device, a DRAM device, a flash memory device, etc., may be disposed at the active layer, and the circuit device may include a plurality of circuit patterns and/or wiring structures. The fourth semiconductor chip 900 may include, e.g., a fourth chip pad 910 adjacent to the first surface 902 of the fourth semiconductor chip 900, which may be a part of the wiring structures.

In some example embodiments, the fourth semiconductor chip 900 may partially overlap the second and/or third semiconductor chips 300 and/or 500 in the third direction D3.

In some example embodiments, a plurality of fourth chip pads 910 may be spaced apart from each other in each, or one or more, of the first and second directions D1 and/or D2, and may be disposed at at least one of neighboring two edge portions of the fourth semiconductor chip 900, which may correspond to the fifth substrate pads 117 of the package substrate 100. Thus, the fourth chip pads 910 may be disposed at edge portions that do not overlap the second and/or third semiconductor chips 300 and/or 500 in the third direction D3.

The second bonding layer 450 may be bonded to the second surface 904 of the fourth semiconductor chip 900 and a portion of the first surface 502 of the third semiconductor chip 500. The second bonding layer 450 may include a material substantially the same as that of the first bonding layer 400, e.g., DAF, NCF, etc.

The second bonding wire 605 may include a fourth adhesion portion 625, which may contact an upper surface of the fourth chip pad 910 of the fourth semiconductor chip 900 and have, e.g., a semi-spherical shape, a fifth adhesion portion 635, which may contact an upper surface of the fifth substrate pad 117 of the package substrate 100 and have, e.g., a semi-spherical shape, and/or a second extension portion 615, which may be disposed between the fourth and fifth adhesion portions 625 and 635, extend in the third direction D3, and be partially bent. In some example embodiments, a plurality of second bonding wires 605 may be spaced apart from each other in each, or one or more, of the first and/or second directions D1 and/or D2, which may correspond to the fourth chip pads 910 and/or the fifth substrate pads 117.

The first bonding wire 600 may include a metal substantially the same as that of the first bonding wire 600, e.g., a metal such as gold, silver, chromium, nickel, molybdenum, tungsten, titanium, tin, etc.

The foregoing is illustrative of some example embodiments and is not to be construed as limiting thereof. Although some example embodiments have been described, those skilled in the art will readily appreciate that many modifications are possible in some example embodiments without materially departing from the novel teachings and advantages of the inventive concepts. Accordingly, all such modifications are intended to be included within the scope of the example embodiments as defined in the claims.

What is claimed is:

1. A semiconductor package comprising:
a package substrate;
a first semiconductor chip on the package substrate;
a conductive connector between the package substrate and the first semiconductor chip, the conductive connector electrically connecting the package substrate to the first semiconductor chip;
a second semiconductor chip contacting an upper surface of the first semiconductor chip;
a vertical bonding wire between the package substrate and the second semiconductor chip, the vertical bonding wire extending in a vertical direction perpendicular to an upper surface of the package substrate, having an upper surface that is coplanar with the upper surface of the first semiconductor chip, and electrically connecting the package substrate to the second semiconductor chip;
a bonding layer contacting an upper surface of the second semiconductor chip; and
a third semiconductor chip contacting an upper surface of the bonding layer.

2. The semiconductor package according to claim 1, wherein
the package substrate includes a first substrate pad, and
the vertical bonding wire includes.
an adhesion portion contacting an upper surface of the first substrate pad; and
a vertical extension portion contacting the adhesion portion and extending in the vertical direction.

3. The semiconductor package according to claim 2, wherein
the second semiconductor chip includes a first chip pad at a lower portion of the second semiconductor chip, and
the vertical extension portion of the vertical bonding wire contacts a lower surface of the first chip pad.

4. The semiconductor package according to claim 3, wherein
a planar area of the second semiconductor chip is greater than a planar area of the first semiconductor chip, and
the first chip pad is at an edge portion of the second semiconductor chip that does not overlap the first semiconductor chip in the vertical direction.

5. The semiconductor package according to claim 3, wherein
the package substrate includes a second substrate pad and the third semiconductor chip includes a second chip pad at an upper portion of the third semiconductor chip, and
the semiconductor package further includes a bonding wire contacting an upper surface of the second substrate pad and an upper surface of the second chip pad.

6. The semiconductor package according to claim 5, wherein a distance from the second substrate pad to a side surface of the package substrate is less than a distance from the first substrate pad to the side surface of the package substrate.

7. The semiconductor package according to claim 1, further comprising:
a plurality of vertical bonding wires spaced apart from each other in a horizontal direction parallel to the upper surface of the package substrate, the vertical bonding wire being one of the plurality of vertical bonding wires,
wherein the plurality of vertical bonding wires are in a rectangular ring shape in a plan view.

8. The semiconductor package according to claim 1, wherein the second and third semiconductor chips have a same planar area.

9. The semiconductor package according to claim 8, wherein a side surface of the third semiconductor chip is aligned with a side surface of the second semiconductor chip in the vertical direction.

10. The semiconductor package according to claim 1, wherein the vertical bonding wire includes gold.

11. The semiconductor package according to claim 1, wherein the bonding layer includes at least one of die attach film (DAF) or a non-conductive film (NCF).

12. A semiconductor package comprising:
a package substrate;
a first semiconductor chip on the package substrate;
a conductive connector between the package substrate and the first semiconductor chip, the conductive connector electrically connecting the package substrate to the first semiconductor chip;
a second semiconductor chip over the first semiconductor chip, the second semiconductor chip being spaced apart from the first semiconductor chip in a vertical direction perpendicular to an upper surface of the substrate;
a vertical bonding wire extending in the vertical direction between the package substrate and the second semiconductor chip;
a bonding layer contacting an upper surface of the second semiconductor chip; and
a third semiconductor chip contacting an upper surface of the bonding layer,
wherein a distance between the first semiconductor chip and the second semiconductor chip in the vertical direction is less than a thickness of the bonding layer in the vertical direction.

13. The semiconductor package according to claim 12, wherein
the package substrate includes a substrate pad, and
the vertical bonding wire includes:
an adhesion portion contacting an upper surface of the substrate pad; and
a vertical extension portion contacting the adhesion portion and extending in the vertical direction.

14. The semiconductor package according to claim 13, wherein
the second semiconductor chip includes a chip pad at a lower portion of the second semiconductor chip, and
the vertical extension portion of the vertical bonding wire contacts a lower surface of the chip pad.

15. The semiconductor package according to claim 14, wherein
a planar area of the second semiconductor chip is greater than a planar area of the first semiconductor chip, and
the first chip pad is at an edge portion of the second semiconductor chip that does not overlap the first semiconductor chip in the vertical direction.

16. The semiconductor package according to claim 12, wherein
the package substrate includes a substrate pad and the third semiconductor chip includes a chip pad at an upper portion of the third semiconductor chip, and
the semiconductor package further includes a bonding wire contacting an upper surface of the substrate pad and an upper surface of the chip pad.

17. The semiconductor package according to claim 12, further comprising:
a plurality of vertical bonding wires spaced apart from each other in a horizontal direction parallel to the upper surface of the package substrate, the vertical bonding wire being one of the plurality of vertical bonding wires,
wherein the plurality of vertical bonding wires are in a rectangular ring shape in a plan view.

18. The semiconductor package according to claim 12, wherein the second and third semiconductor chips have a same planar area.

19. A semiconductor package comprising:
a package substrate;
a first semiconductor chip on the package substrate;
a conductive connector between the package substrate and the first semiconductor chip, the conductive connector electrically connecting the package substrate to the first semiconductor chip;
a second semiconductor chip contacting an upper surface of the first semiconductor chip;
a vertical bonding wire between the package substrate and the second semiconductor chip, the vertical bonding wire extending in a vertical direction perpendicular to an upper surface of the package substrate, having an upper surface coplanar with the upper surface of the first semiconductor chip, and electrically connecting the package substrate to the second semiconductor chip;
a first bonding layer contacting an upper surface of the second semiconductor chip;
a third semiconductor chip contacting an upper surface of the first bonding layer;
a first bonding wire electrically connecting the third semiconductor chip to the package substrate;
a second bonding layer contacting an upper surface of the third semiconductor chip;
a fourth semiconductor chip contacting an upper surface of the second bonding layer; and
a second bonding wire electrically connecting the fourth semiconductor chip to the package substrate.

20. The semiconductor package according to claim 19, wherein:
the package substrate includes
a first side surface,
a second side surface opposite the first side surface in a first direction parallel to an upper surface of the package substrate,
a third side surface,
a fourth side surface opposite the third side surface in a second direction parallel to the upper surface of the package substrate and crossing the first direction,
first edge portions adjacent to the first side surfaces,
second edge portions adjacent to the second side surfaces,
third edge portions adjacent to the third side surfaces,
fourth edge portions adjacent to the fourth side surface,
first substrate pads at the first edge portions and the third edge portions, and
second substrate pads at the second edge portions and the fourth edge portions;
the semiconductor package further includes a plurality of first bonding wires contacting the first substrate pads, respectively, the first bonding wire being one of the plurality of first bonding wires; and
the semiconductor package further includes a plurality of second bonding wires contacting the second substrate pads, respectively, the second bonding wire being one of the plurality of second bonding wires.
